(19) United States
(12) Patent Application Publication
(10) Pub. No.: US 2025/0258247 A1
(43) Pub. Date: Aug. 14, 2025

(54) DYNAMIC TIME WARPING (DTW)-BASED REAL-TIME DIAGNOSIS METHOD FOR COMMUTATION FAILURE (CF) OF PHASE-CONTROLLED CONVERTER

(71) Applicant: Hefei Institutes of Physical Science, CAS, Hefei (CN)

(72) Inventors: Xiaojiao CHEN, Hefei (CN); Zhenyu XUE, Hefei (CN); Xiaoxiao YANG, Hefei (CN); Liansheng HUANG, Hefei (CN); Yan SHEN, Hefei (CN); Shiying HE, Hefei (CN); Xiuqing ZHANG, Hefei (CN); Ying ZUO, Hefei (CN)

(21) Appl. No.: 19/170,029

(22) Filed: Apr. 3, 2025

(30) Foreign Application Priority Data
Aug. 22, 2024 (CN) 202411160275.1

(51) Int. Cl. G01R 31/40; H02M 7/155

(52) U.S. Cl. CPC G01R 31/40; H02M 7/155

(57) ABSTRACT

Provided is a dynamic time warping (DTW)-based real-time diagnosis method for a commutation failure (CF). The method includes: designing a time series template S0 containing a change of a firing angle of a phase-controlled rectifier, and having a length n and a Euclidean distance L; using an n*n matrix M to represent a Euclidean distance between each point in the S0 and each point in the Si, and constricting the matrix M with an Itakura window; calculating values of the matrix M in the search range H; setting different weights for data at different locations, and searching a shortest path L* from point (x₁, y₁) to point (xₙ, yₙ) of the matrix; and setting a range of the distance L of the S0 as λ, determining that the CF fault occurs if the L* is greater than λL, or otherwise, determining that a system works normally.

### CROSS REFERENCE TO RELATED APPLICATION

This patent application claims the benefit and priority of Chinese Patent Application No. 202411160275.1, filed with the China National Intellectual Property Administration on Aug. 22, 2024, the disclosure of which is incorporated by reference herein in its entirety as part of the present application.

### TECHNICAL FIELD

The present disclosure relates to the field of phase-controlled converters, and in particular to, a dynamic time warping (DTW)-based real-time diagnosis method for a commutation failure (CF) of a phase-controlled converter.

### BACKGROUND

As one of critical subsystems of a magnetic confinement fusion (MCF) device, the fusion magnet power supply provides the necessary engineering means for generation, confinement, maintenance and heating of plasmas. At present, the fusion magnet power supply realizes the high-power and high-current output mainly with a phase-controlled converter. However, the CF is the inherent defect of the phase-controlled converter. Continuous CF (CCF) will lead to emergency shutdown or even control failure of the power supply, resulting in plasma disruption to pose a threat to safety of the device. When the CF of the phase-controlled converter occurs for the first time, if the fault can be diagnosed in real time and the control parameters can be adjusted, the CF fault can be prevented effectively to ensure normal operation of the system. Hence, timeliness and accuracy for diagnosing the CF fault are highly demanding.

With desirable robustness and nonlinear alignment characteristic, the DTW can adjust the distance measurement method according to different application scenarios and has been widely applied to the field of real-time diagnosis. The DTW mainly includes local DTW, global DTW, window DTW, etc. The window DTW includes fixed window DTW and dynamic window DTW. In some occasions where both accuracy and amount of calculation are required to some extent, the DTW is significantly effective and widely applied. However, due to the large amount of calculation, numerous matrix elements to be calculated, and sensitivity to abnormal values, the accuracy of the DTW will be reduced. Since the firing angle of the fusion magnet power supply system is dynamically changing, when the DTW is used to diagnose the CF fault, the designed template should be compatible to different working conditions where the firing angle in the inverting state changes quickly in real time, or the firing angle is constant in operation.

### SUMMARY

In view of the above problem, the present disclosure provides a DTW-based real-time diagnosis method for a CF of a phase-controlled converter, to determine a fault location, and improve accuracy of the algorithm and timeliness for determining the fault.

To solve the above technical problem, the present disclosure adopts the following technical solutions:

A DTW-based real-time diagnosis method for a CF of a phase-controlled converter includes the following steps:
step 1: designing a voltage waveform with a time series of a length n as a time series template S0, S0=(y₁−yₙ), and calculating a Euclidean distance L of the time series template S0, y₁−yₙ being n pieces of data in the time series template S0;
step 2: taking data of n sampling points in a present acquired time series as an input sample Si, Si=(x₁−xₙ), aligning a start point and an end point of the time series template S0 with a start point and an end point of the input sample Si, and checking monotonicity of the time series template S0 and monotonicity of the input sample Si to ensure no crossed correspondence, x₁−xₙ being data of n sampling points in the input sample Si, and i representing an ith input sample;
step 3: establishing a coordinate system with the data of the n sampling points in the input sample Si=(x₁−xₙ) as an abscissa, and the n pieces of data in the time series template S0=(y₁−yₙ) as an ordinate, an n*n matrix M representing a Euclidean distance between each point in the time series template S0 and each point in the input sample Si, and constricting the n*n matrix M with an Itakura window to determine a search range H;
step 4: calculating only values of matrix elements of the n*n matrix M in the search range H;
step 5: in the search range H, setting different weights for the values of the matrix elements in the n*n matrix M, and searching a shortest path L* on which a sum of values of matrix elements in the n*n matrix M from a coordinate point (x₁, y₁) to a coordinate point (xₙ, yₙ) is minimum;
step 6: setting a range of the Euclidean distance L of the time series template S0 as λ; and
step 7: if the shortest path L* is greater than λL, determining that the CF fault occurs, or otherwise, determining that a system works normally.

Preferably, the step 1 includes:
step 1.1: setting a range of a firing angle: since the CF occurs in an inverting state of the phase-controlled converter, setting the range of the firing angle as π/2−5π/6;
step 1.2: calculating a distance L′ between a working voltage corresponding to a firing angle α₁ and a working voltage corresponding to a firing angle α₂ according to a Euclidean distance formula:

$${L}^{′} = U \sum \sqrt{{( \sqrt{6} sin ( wt + {α}_{1} + x ) - \sqrt{6} sin ( wt + {α}_{2} + x ) )}^{2}} ,$$

where, x is a phase angle of a sampling point, U is an input voltage, w is an angular frequency, and t is time;
step 1.3: obtaining a universal Euclidean distance Lᵤ:

$${L}_{u} = U \sum \sqrt{{( \sqrt{6} sin ( wt + {α}_{1} + x ) - {U}_{d} ( {α}_{1} ) - \sqrt{6} sin ( wt + {α}_{2} + x ) + {U}_{d} ( {α}_{2} ) )}^{2}} ,$$

where, an average U_{d} for line voltages is:

U_{d}=2.34U cos α,
where, α is the firing angle;
step 1.4: setting the universal Euclidean distance Lᵤ and the input voltage U as a positively related functional relationship, specifically:

Lᵤ=kU,
where, a coefficient k is:

$$k = \sum \sqrt{{( \sqrt{6} sin ( wt + {α}_{1} + x ) - {U}_{d} ( {α}_{1} ) - \sqrt{6} sin ( wt + {α}_{2} + x ) + {U}_{d} ( {α}_{2} ) )}^{2}} ;$$

step 1.5: setting the firing angle α₁ as π/2 and the firing angle α₂ as π/2, sequentially increasing the firing angle α₂ by π/36 until the firing angle α₂ is 5π/6, and calculating and drawing a first curve; then setting the firing angle α₁ as π/2+π/36 and the firing angle α₂ as π/2, sequentially increasing the firing angle α₂ by π/36 until the firing angle α₂ is 5π/6, calculating and drawing a second curve; and by the same reasoning, calculating and drawing 13 curves, and displaying a change of the coefficient k at each firing angle, thereby obtaining a coefficient map;
step 1.6: according to the coefficient map, obtaining a ninth curve with a corresponding Euclidean distance being not greater than 6 U at maximum, specifically setting a time series of a voltage waveform at the firing angle α₁ of 130° as the optimal time series template; and
step 1.7: according to a range of the corresponding Euclidean distance L*ᵤ: 0≤L*ᵤ≤6U, determining the Euclidean distance of the optimal time series template as 6 U.

Preferably, the step 5 includes: setting weights corresponding to front n/3 matrix elements as q1, weights corresponding to middle n/3−5n/6 matrix elements as q2, and weights corresponding to rear 5n/6−n matrix elements as q3.

Preferably, in the step 3, an element Mₘⱼ in the n*n matrix M is calculated by:

$${M}_{mj} = \sqrt{{\vert {x}_{m} - {y}_{m} \vert}^{2}} , m = 1 , 2 … n ; j = 1 , 2 … n ,$$

where, xₘ represents data of an mth sampling point in the input sample Si, yₘ represents mth data in the time series template S0, and j is an index value.

Preferably, in the step 3, the search range H is constricted in a parallelogram with slopes being ½ and 2 respectively, a path is planned from the coordinate point (x₁, y₁) to the coordinate point (xₙ, yₙ), and four coordinate points of the parallelogram of the search range H are respectively (x₁, y₁), (x_{n/3}, y_{2n/3}), (x_{2n/3}, y_{n/3}), and (xₙ, yₙ).

Preferably, in the step 6, the λ is 1.5.

Preferably, q1 is 0.5, q2 is 0.8, and q3 is 1.3.

The present disclosure has the following beneficial effects:

For the steady system with the unchanged firing angle, such as operation with the constant firing angle in high voltage direct current (HVDC) transmission, and the dynamic system with the real-time changing firing angle, such as the fusion magnet power supply system using the phase-controlled rectifier solution, the present disclosure can accurately diagnose the CF fault in real time by calculating the change of each firing angle in the whole inverting range. Moreover, by applying different weights to different locations of the series, the present disclosure optimizes the calculation process, effectively improves the sensitivity of the algorithm to the abnormal value of the phase-controlled converter, can determine the fault location more quickly, and improves the accuracy of the algorithm and the timeliness for determining the fault.

### BRIEF DESCRIPTION OF THE DRAWINGS

FIG. 1 is a schematic view of a three-phase fully controlled converter unit;

FIG. 2 is a schematic view of a voltage waveform in an active inverting state;

FIG. 3 is a coefficient map for Euclidean distances at different firing angles;

FIG. 4 is a schematic view of an Itakura constraint window;

FIG. 5A is a schematic view of a variable weight;

FIG. 5B is a schematic view of a variable weight window;

FIG. 6 is a flowchart of a DTW-based real-time diagnosis method for a CF of a phase-controlled converter according to the present disclosure;

FIG. 7A illustrates a fault detection waveform in response to 20% of single-phase decay of a single-phase fully controlled rectifier circuit;

FIG. 7B illustrates a fault voltage changing waveform in response to 20% of single-phase decay of a single-phase fully controlled rectifier circuit;

FIG. 7C illustrates a fault current changing waveform in response to 20% of single-phase decay of a single-phase fully controlled rectifier circuit;

FIG. 8A illustrates a fault detection waveform in response to 40% of single-phase decay of a single-phase fully controlled rectifier circuit;

FIG. 8B illustrates a fault voltage changing waveform in response to 40% of single-phase decay of a single-phase fully controlled rectifier circuit;

FIG. 8C illustrates a fault current changing waveform in response to 40% of single-phase decay of a single-phase fully controlled rectifier circuit;

FIG. 9A illustrates a fault detection waveform in response to 60% of single-phase decay of a single-phase fully controlled rectifier circuit;

FIG. 9B illustrates a fault voltage changing waveform in response to 60% of single-phase decay of a single-phase fully controlled rectifier circuit;

FIG. 9C illustrates a fault current changing waveform in response to 60% of single-phase decay of a single-phase fully controlled rectifier circuit;

FIG. 10A illustrates a fault detection waveform in response to 80% of single-phase decay of a single-phase fully controlled rectifier circuit;

FIG. 10B illustrates a fault voltage changing waveform in response to 80% of single-phase decay of a single-phase fully controlled rectifier circuit;

FIG. 10C illustrates a fault current changing waveform in response to 80% of single-phase decay of a single-phase fully controlled rectifier circuit;

FIG. 11A illustrates a fault detection waveform in response to 20% of single-phase decay of a three-phase fully controlled rectifier circuit;

FIG. 11B illustrates a fault voltage changing waveform in response to 20% of three-phase decay of a single-phase fully controlled rectifier circuit;

FIG. 11C illustrates a fault current changing waveform in response to 20% of single-phase decay of a three-phase fully controlled rectifier circuit;

FIG. 12A illustrates a diagnostic result in response to a pulse loss;

FIG. 12B illustrates a change of a voltage waveform in response to a pulse loss; and

FIG. 12C illustrates a change of a current waveform in response to a pulse loss.

### DETAILED DESCRIPTION OF THE EMBODIMENTS

In order to make the objectives, technical solutions, and advantages of the present disclosure more clear, the present disclosure is further described in detail below with reference to the accompanying drawings and embodiments. It should be understood that the specific embodiments described herein are intended merely to explain the present disclosure, rather than to limit the present disclosure. Further, the technical features involved in the various embodiments of the present disclosure described below may be combined with each other as long as they do not constitute a conflict with each other.

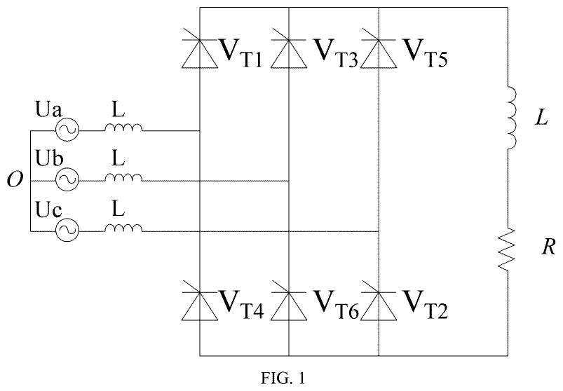

The experimental advanced superconducting tokamak (EAST) poloidal field power supply (PFPS) system uses a phase-controlled rectifier solution. Each set of power supply includes four three-phase fully controlled converter units. FIG. 1 shows a topology of the single three-phase fully controlled converter unit. A first thyristor V_{T1} and a fourth thyristor V_{T4} are connected in series. A third thyristor V_{T3} and a sixth thyristor V_{T6} are connected in series. A fifth thyristor V_{T5} and a second thyristor V_{T2} are connected in series. A loading inductor and a loop resistor are connected in series. After connected in series, the above components are connected in parallel. A three-phase power supply Uₐ, U_{b}, U_{c} includes one end connected to a ground point O, and the other end connected to loading inductors L and then connected between the first thyristor V_{T1} and the fourth thyristor V_{T4}, between the third thyristor V_{T3} and the sixth thyristor V_{T6}, and between the fifth thyristor V_{T5} and the second thyristor V_{T2}. Each switching device (namely the thyristor) is controlled by one control signal, and configured to control a direction and a magnitude of a current. The switching device is turned on or off through a firing pulse. That is, the rectifier bridge used by the present disclosure is a bridge structure. Every two switching devices form one bridge arm. There are totally three bridge arms that are respectively connected to three phases of the three-phase power supply. Switching devices at an upper end and a lower end of each bridge arm are complemented to each other. That is, when one switching device is connected, the other switching device is disconnected, thereby forming a six-pulse rectifier.

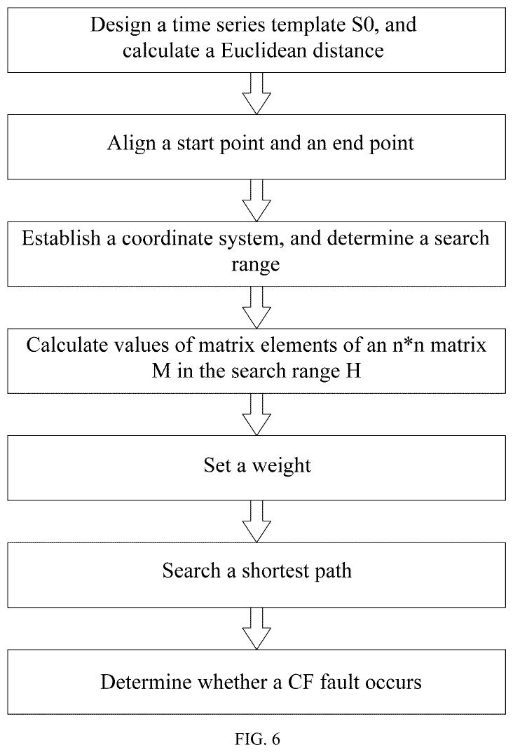

As shown in FIG. 6, the present disclosure provides a DTW-based real-time diagnosis method for a CF of a phase-controlled converter, including the following steps:
Step 1: A voltage waveform with a time series of a length n is designed as a time series template S0, S0=(y₁−yₙ), and a Euclidean distance L of the time series template S0 is calculated, y₁−yₙ being n pieces of data in the time series template S0, namely a signal data series sampled and to be diagnosed in FIG. 6. Step 2: Data of n sampling points in a present acquired time series is taken as an input sample Si, Si=(x₁−xₙ), a start point and an end point of the time series template S0 are aligned with a start point and an end point of the input sample Si, and monotonicity of the time series template S0 and monotonicity of the input sample Si are checked to ensure no crossed correspondence, x₁−xₙ being data of n sampling points in the input sample Si, and i representing an ith input sample.
Step 3: A coordinate system with the data of the n sampling points in the input sample Si=(x₁−xₙ) as an abscissa, and the n pieces of data in the time series template S0=(y₁−yₙ) as an ordinate is established, an n*n matrix M representing a Euclidean distance between each point in the time series template S0 and each point in the input sample Si, and the n*n matrix M is constricted with an Itakura window to determine a search range H.
Step 4: Only values of matrix elements of the n*n matrix M in the search range H are calculated.
Step 5: In the search range H, different weights are set for the values of the matrix elements in the n*n matrix M, and a shortest path L* on which a sum of values of matrix elements in the n*n matrix M from a coordinate point (x₁, y₁) to a coordinate point (xₙ, yₙ) is minimum is searched.
Step 6: A range of the Euclidean distance L of the time series template S0 is set as λ.
Step 7: If the shortest path L* is greater than λL, it is determined that the CF fault occurs, or otherwise, it is determined that a system works normally.

Specifically, Step 1 includes:

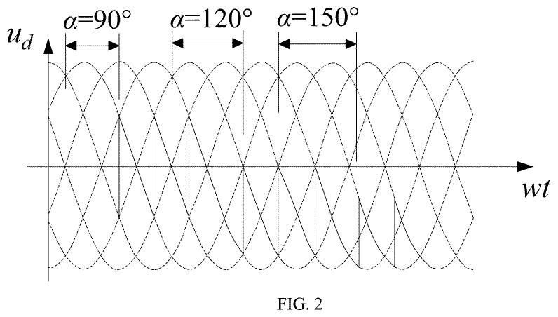

To diagnose the CF fault with the DTW, an appropriate template is searched first. The CF occurs in an inverting state of the thyristor converter, with a firing angle in a range of π/2−π at maximum. Considering that an inverting angle of the actual system cannot reach π, an upper limit of the inverting angle can be adjusted according to different systems. Herein, the firing angle is in a range of π/2−5π/6, and the voltage waveform in the active inverting state is as shown in FIG. 2. Herein, u_{d} is an output voltage, ω is an angular frequency, and t is time. As can be seen from FIG. 2, waveforms corresponding to different firing angles vary a lot in term of shape and amplitude. As the firing angle increases, the amplitude of the output voltage increases.

The sampling frequency is 10 kHz, the six-pulse period is 20 ms, and each pulse is 3.3 ms, and corresponds to 33 sampling points xₚ:

$${x}_{p} = [ \frac{1}{33} \frac{2}{33} \frac{3}{33} … \frac{33}{33} ] .$$

Through expansion,

$$x = [ \frac{π}{3} * \frac{1}{33} \frac{π}{3} * \frac{2}{33} \frac{π}{3} * \frac{3}{33} … \frac{π}{3} * \frac{33}{33} ]$$

can be obtained.

A line voltage Uₓ is calculated as:

$${U}_{x} = \sqrt{6} U sin ( wt + α + β ) .$$

Herein, α is the firing angle, β is a phase angle of a sampling point, U is an input voltage, w is the angular frequency, and t is the time. According to characteristics of the six-pulse voltage waveform, the line voltage corresponding to each sampling point xₚ is calculated.

In order that the time series template can be compatible to a steady system with the unchanged firing angle, and a dynamic system in which the firing angle changes in real time in the whole inverting angle, a distance L′ between a working voltage corresponding to a firing angle α₁ and a working voltage corresponding to a firing angle α₂ is calculated according to a Euclidean distance formula:

$${L}^{′} = U \sum \sqrt{{( \sqrt{6} sin ( wt + {α}_{1} + x ) - \sqrt{6} s i n ( w t + {α}_{2} + x ) )}^{2}} .$$

An average for line voltages at the two firing angles can be removed, and a universal Euclidean distance Lᵤ is calculated by:

$${L}_{u} = U \sum \sqrt{{( \sqrt{6} sin ( wt + {α}_{1} + x ) - {U}_{d} ( {α}_{1} ) - \sqrt{6} sin ( wt + {α}_{2} + x ) + {U}_{d} ( {α}_{2} ) )}^{2}} .$$

The average U_{d} for the line voltages is:

U_{d}=2.34U cos α.

A coefficient k is set as:

$$k = \sum \sqrt{{( \sqrt{6} sin ( wt + {α}_{1} + x ) - {U}_{d} ( {α}_{1} ) - \sqrt{6} sin ( wt + {α}_{2} + x ) + {U}_{d} ( {α}_{2} ) )}^{2}} .$$

The universal Euclidean distance Lᵤ and the input voltage U are a positively related functional relationship, specifically:

Lᵤ=kU.

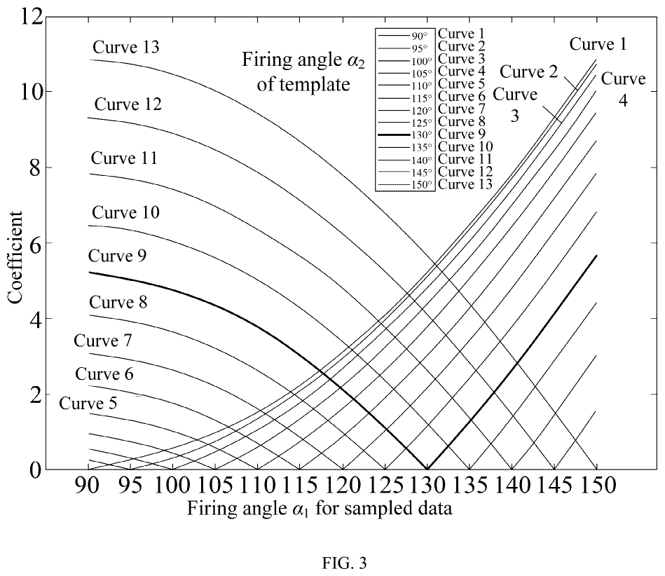

The firing angle α₁ is set as π/2 and the firing angle α₂ is set as π/2, the firing angle α₂ is sequentially increased by π/36 until the firing angle α₂ is 5π/6, and a first curve is calculated and drawn. Then the firing angle α₁ is set as π/2+π/36 and the firing angle α₂ is set as π/2, the firing angle α₂ is sequentially increased by π/36 until the firing angle α₂ is 5π/6, and a second curve is calculated and drawn. By the same reasoning, 13 curves are calculated and drawn, and a change of the coefficient at each firing angle is displayed, thereby obtaining a coefficient map, as shown in FIG. 3. In all firing angles of FIG. 3, the time series corresponding to the firing angle at the minimum Euclidean distance is determined as the optimal time series template. According to the coefficient map, a ninth curve with a corresponding Euclidean distance being not greater than 6 U at maximum is obtained. That is, a time series of a voltage waveform at the firing angle α₁ of 130° is determined as the optimal time series template.

A range of the corresponding Euclidean distance L*ᵤ is:

0≤L*ᵤ≤6U.

Hence, the Euclidean distance of the optimal time series template is 6 U.

Specifically, in Step 3, a coordinate system with the data of the n sampling points in the Si=(x₁−xₙ) as an abscissa, and the n pieces of data in the S0=(y₁−yₙ) as an ordinate is established. An element Mₘⱼ in the matrix M is calculated by:

$${M}_{mj} = \sqrt{{\vert {x}_{m} - {y}_{m} \vert}^{2}} , m = 1 , 2 … n ; j = 1 , 2 … n .$$

Herein, xₘ represents data of an mth sampling point in the input sample Si, yₘ represents mth data in the time series template S0, and j is an index value.

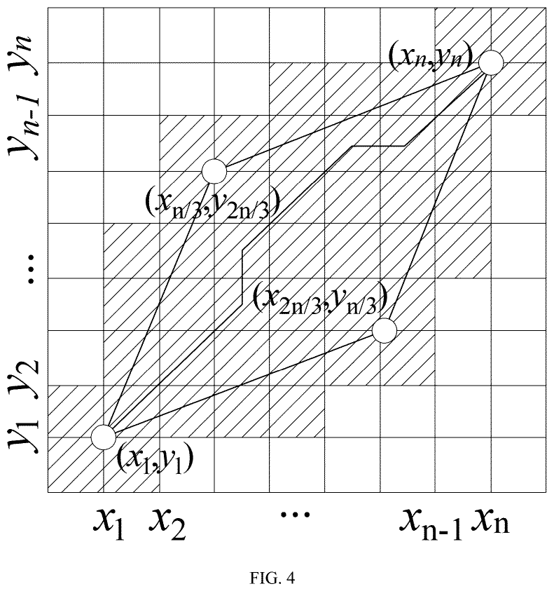

The search range His constricted in a parallelogram with slopes being ½ and 2 respectively. A path is planned from the coordinate point (x₁, y₁) to the coordinate point (xₙ, yₙ). As shown in FIG. 4, four coordinate points of the parallelogram of the search range H are respectively (x₁, y₁), (x_{n/3}, y_{2n/3}), (x_{2n/3}, y_{n/3}), and (xₙ, yₙ).

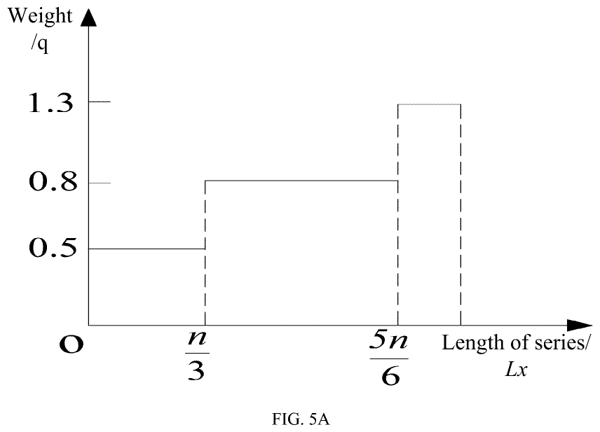

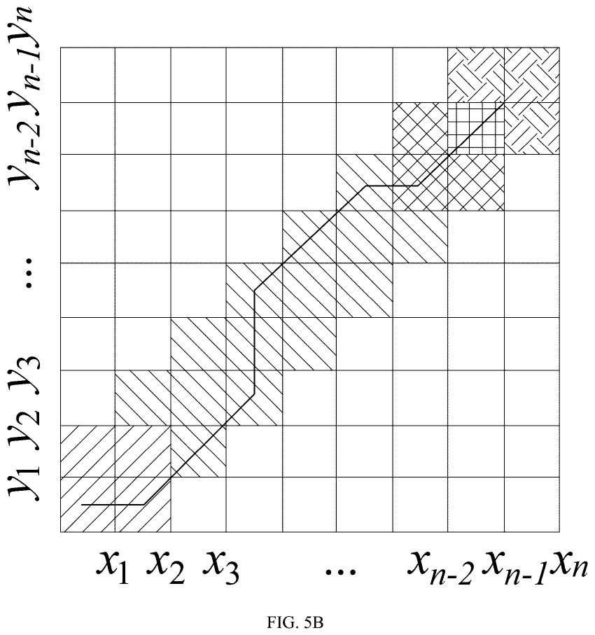

Specifically, in Step 5, the front ⅓ part of the input sample Si contains least information on the abnormal values, and is assigned with a low weight. The middle ½ part in the time series reflects a part of similarities on the whole path, and is assigned with a medium weight. The rear ⅙ part of the one-dimensional time series contains most information on the abnormal values, and is assigned with a high weight. The weights are designed according to an actual test effect. As shown in FIG. 5A and FIG. 5B, FIG. 5A is a schematic view of a variable weight, and FIG. 5B is a schematic view of a variable weight window. Herein, n is a length of the acquired series, xᵢ is an ith sampling point of the acquired time series, and yᵢ is ith data in the template. In the search range, different weights are set for data at different locations of the time series. As shown in FIG. 5A, weights corresponding to front n/3 matrix elements are set as q1, weights corresponding to middle n/3−5n/6 matrix elements are set as q2, and weights corresponding to rear 5n/6−n matrix elements are set as q3. The q1, the q2 and the q3 are set according to an actual detection result. The q1 is 0.5, the q2 is 0.8, and the q3 is 1.3.

In view of various external disturbances such as noise in actual engineering, the range of the Euclidean distance L of the time series template S0 is set as λ. The λ can be adjusted according to the actual test effect, and is 1.5 herein. If the corresponding Euclidean distance L* is greater than λL, it is determined that the CF fault occurs. Or otherwise, it is determined that a system works normally.

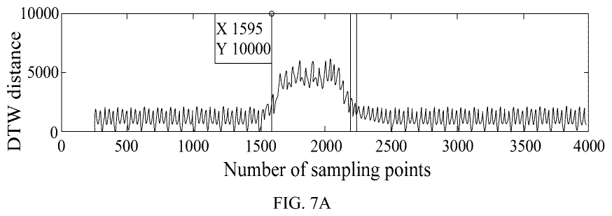

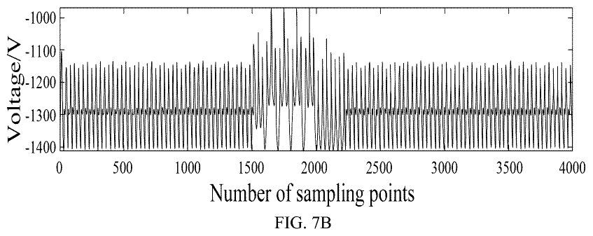

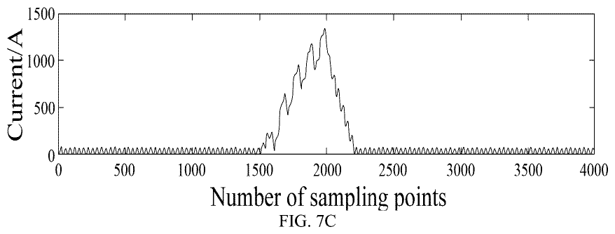

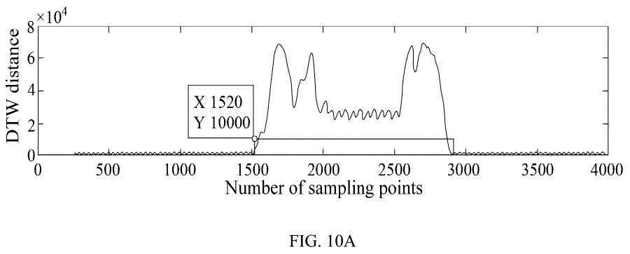

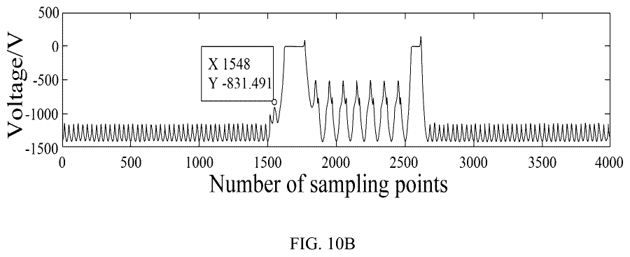

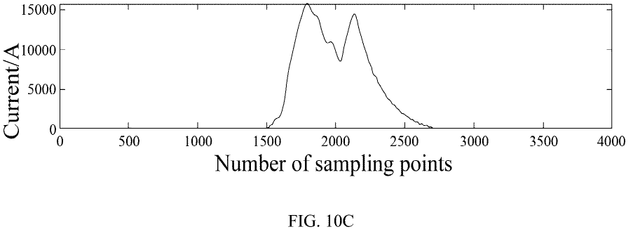

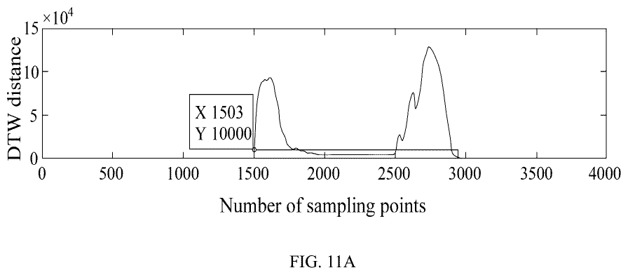

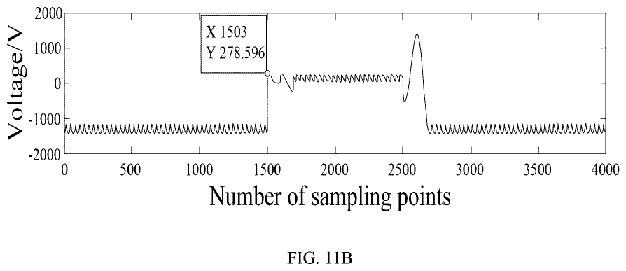

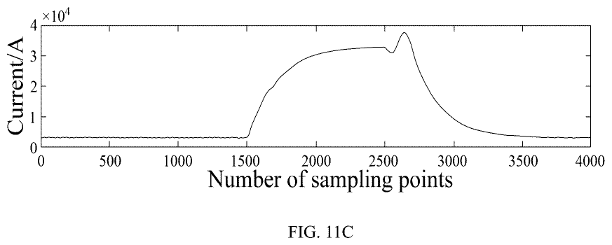

FIG. 7A to FIG. 12A illustrate diagnostic results of the method, and respectively describe a diagnostic result in response to 20% of single-phase decay, a diagnostic result in response to 40% of single-phase decay, a diagnostic result in response to 60% of single-phase decay, a diagnostic result in response to 80% of single-phase decay, a diagnostic result in response to 20% of three-phase decay, and a diagnostic result in response to a pulse loss. The sampling point serves as the abscissa, and the DTW distance serves as the ordinate. The curve represents the DTW distance, and the straight line represents the fault detection result.

FIG. 7B to FIG. 12B respectively describe a change of a voltage waveform in response to 20% of single-phase decay, a change of a voltage waveform in response to 40% of single-phase decay, a change of a voltage waveform in response to 60% of single-phase decay, a change of a voltage waveform in response to 80% of single-phase decay, a change of a voltage waveform in response to 20% of three-phase decay, and a change of a voltage waveform in response to a pulse loss. The sampling point serves as the abscissa, and the voltage value serves as the ordinate.

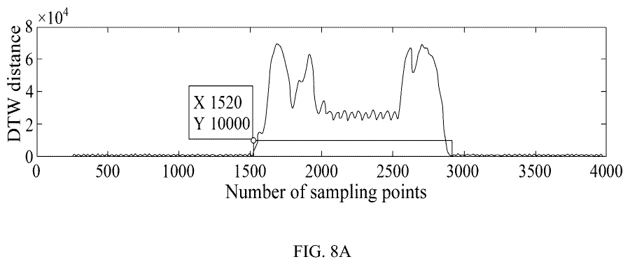

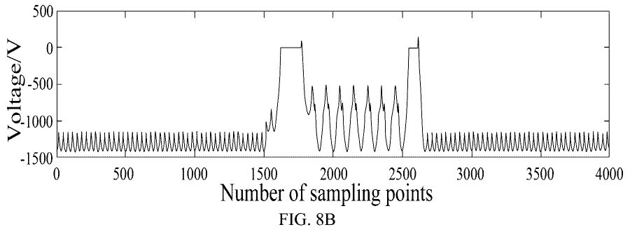

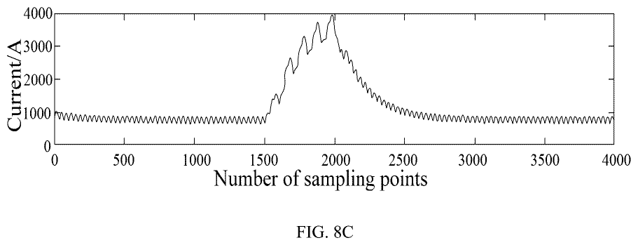

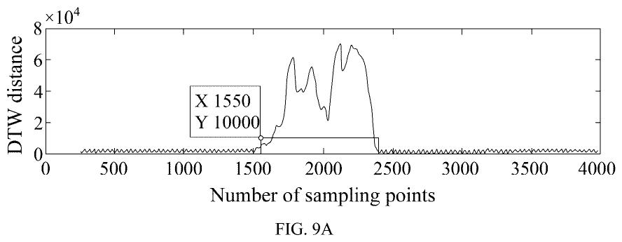

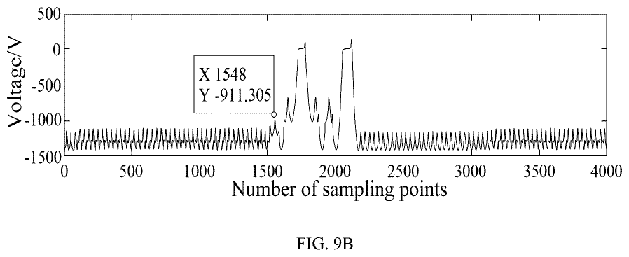

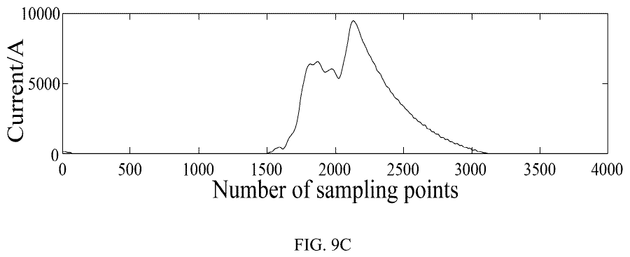

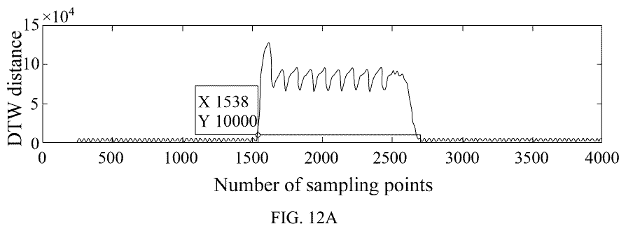

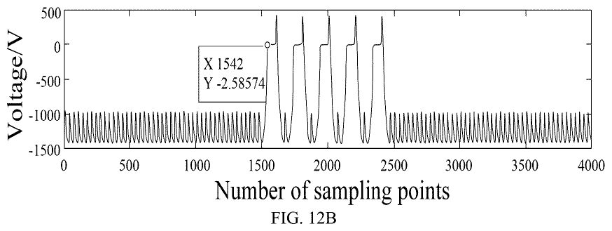

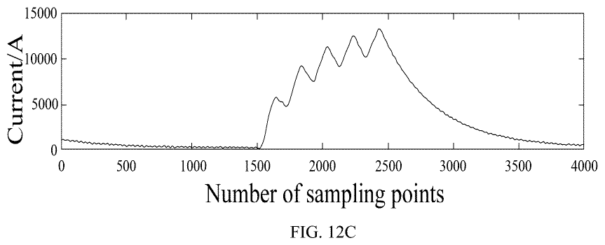

FIG. 7C to FIG. 12C respectively describe a change of a current waveform in response to 20% of single-phase decay, a change of a current waveform in response to 40% of single-phase decay, a change of a current waveform in response to 60% of single-phase decay, a change of a current waveform in response to 80% of single-phase decay, a change of a current waveform in response to 20% of three-phase decay, and a change of a current waveform in response to a pulse loss. The sampling point serves as the abscissa, and the current value serves as the ordinate. In normal operation, the DTW distance of the voltage signal is steady, conforms to the multi-pulse law, and does not show the abnormal value in a certain range of amplitudes. As can be seen from FIG. 7B and FIG. 7C, after 0.15 s of fault injection, the current at the direct-current (DC) side is fluctuated. The voltage at the DC side does not show the obvious CF phenomenon, although the waveform does not conform to the multi-pulse law. It can be observed from FIG. 7A that the CF occurs possibly after 95 sampling points. As can be seen from FIG. 8B and FIG. 8C, in response to 40% of voltage decay at an alternating-current (AC) side, the CF fault occurs obviously. After 0.15 s of fault injection, the waveform in the first commutation period and the waveform in the second commutation period are distorted, and the CF occurs in the third commutation period. It can be observed from FIG. 8A that the CF, namely waveform distortion in the first commutation period, occurs possibly after 20 sampling points. Then, FIG. 9A to FIG. 11A respectively show CF determining situations in response to 60% of voltage decay at the AC side, 80% of voltage decay at the AC side, and 20% of three-phase decay, with results similar to those in FIG. 7A. FIG. 9B to FIG. 11B respectively show changes of voltage waveforms in response to 60% of voltage decay at the AC side, 80% of voltage decay at the AC side, and 20% of three-phase decay. FIG. 9C to FIG. 12C respectively show changes of current waveforms in response to 60% of voltage decay at the AC side, 80% of voltage decay at the AC side, and 20% of three-phase decay. The pulse loss is determined as shown in FIG. 12A. After the fault occurs, the voltage is fluctuated obviously, and the CF occurs after 38 sampling points. FIG. 12B and FIG. 12C respectively show a voltage waveform and a current waveform in response to the pulse loss.

What is claimed is:

1. A dynamic time warping (DTW)-based real-time diagnosis method for a commutation failure (CF) of a phase-controlled converter, comprising the following steps:
step 1: designing a voltage waveform with a time series of a length n as a time series template S0, S0=(y₁−yₙ), and calculating a Euclidean distance L of the time series template S0, y₁−yₙ being n pieces of data in the time series template S0;
step 2: taking data of n sampling points in a present acquired time series as an input sample Si, Si=(x₁−xₙ), aligning a start point and an end point of the time series template S0 with a start point and an end point of the input sample Si, and checking monotonicity of the time series template S0 and monotonicity of the input sample Si to ensure no crossed correspondence, x₁−xₙ being data of n sampling points in the input sample Si, and i representing an ith input sample;
step 3: establishing a coordinate system with the data of the n sampling points in the input sample Si=(x₁−xₙ) as an abscissa, and the n pieces of data in the time series template S0=(y₁−yₙ) as an ordinate, an n*n matrix M representing a Euclidean distance between each point in the time series template S0 and each point in the input sample Si, and constricting the n*n matrix M with an Itakura window to determine a search range H;
step 4: calculating only values of matrix elements of the n*n matrix M in the search range H;
step 5: in the search range H, setting different weights for the values of the matrix elements in the n*n matrix M, and searching a shortest path L* on which a sum of values of matrix elements in the n*n matrix M from a coordinate point (x₁, y₁) to a coordinate point (xₙ, yₙ) is minimum;
step 6: setting a range of the Euclidean distance L of the time series template S0 as λ; and
step 7: if the shortest path L* is greater than λL, determining that the CF fault occurs, or otherwise, determining that a system works normally.

2. The DTW-based real-time diagnosis method for a CF of a phase-controlled converter according to claim 1, wherein the step 1 comprises:
step 1.1: setting a range of a firing angle: since the CF occurs in an inverting state of the phase-controlled converter, setting the range of the firing angle as π/2−5π/6;
step 1.2: calculating a distance L′ between a working voltage corresponding to a firing angle α₁ and a working voltage corresponding to a firing angle α₂ according to a Euclidean distance formula:
$${L}^{′} = U \sum \sqrt{{( \sqrt{6} sin ( wt + {α}_{1} + x ) - \sqrt{6} sin ( wt + {α}_{2} + x ) )}^{2}} ,$$
wherein, x is a phase angle of a sampling point, U is an input voltage, w is an angular frequency, and t is time;
step 1.3: obtaining a universal Euclidean distance Lᵤ:
$${L}_{u} = U \sum \sqrt{{( \sqrt{6} sin ( wt + {α}_{1} + x ) - {U}_{d} ( {α}_{1} ) - \sqrt{6} sin ( wt + {α}_{2} + x ) + {U}_{d} ( {α}_{2} ) )}^{2}} ,$$
wherein, an average U_{d} for line voltages is:
U_{d}=2.34U cos α,
wherein, α is the firing angle;
step 1.4: setting the universal Euclidean distance Lᵤ and the input voltage U as a positively related functional relationship, specifically:
Lᵤ=kU,
wherein, a coefficient k is:
$$k = \sum \sqrt{{( \sqrt{6} sin ( wt + {α}_{1} + x ) - {U}_{d} ( {α}_{1} ) - \sqrt{6} sin ( wt + {α}_{2} + x ) + {U}_{d} ( {α}_{2} ) )}^{2}} ,$$
step 1.5: setting the firing angle α₁ as π/2 and the firing angle α₂ as π/2, sequentially increasing the firing angle α₂ by π/36 until the firing angle α₂ is 5π/6, and calculating and drawing a first curve; then setting the firing angle α₁ as π/2+π/36 and the firing angle α₂ as π/2, sequentially increasing the firing angle α₂ by π/36 until the firing angle α₂ is 5π/6, and calculating and drawing a second curve; and by the same reasoning, calculating and drawing 13 curves, and displaying a change of the coefficient k at each firing angle, thereby obtaining a coefficient map;
step 1.6: according to the coefficient map, obtaining a ninth curve with a corresponding Euclidean distance being not greater than 6 U at maximum, specifically setting a time series of a voltage waveform at the firing angle α₁ of 130° as the optimal time series template; and
step 1.7: according to a range of the corresponding Euclidean distance L*ᵤ: 0≤L*ᵤ≤6U, determining the Euclidean distance of the optimal time series template as 6 U.

3. The DTW-based real-time diagnosis method for a CF of a phase-controlled converter according to claim 1, wherein the step 5 comprises: setting weights corresponding to front n/3 matrix elements as q1, weights corresponding to middle n/3−5n/6 matrix elements as q2, and weights corresponding to rear 5n/6−n matrix elements as q3.

4. The DTW-based real-time diagnosis method for a CF of a phase-controlled converter according to claim 1, wherein in the step 3, an element Mₘⱼ in the n*n matrix M is calculated by:
$${M}_{mj} = \sqrt{{\vert {x}_{m} - {y}_{m} \vert}^{2}} , m = 1 , 2 … n ; j = 1 , 2 … n ,$$
wherein, xₘ represents data of an mth sampling point in the input sample Si, yₘ represents mth data in the time series template S0, and j is an index value.

5. The DTW-based real-time diagnosis method for a CF of a phase-controlled converter according to claim 1, wherein in the step 3, the search range H is constricted in a parallelogram with slopes being ½ and 2 respectively, a path is planned from the coordinate point (x₁, y₁) to the coordinate point (xₙ, yₙ), and four coordinate points of the parallelogram of the search range H are respectively (x₁, y₁), (x_{n/3}, y_{2n/3}), (x_{2n/3}, y_{n/3}), and (xₙ, yₙ).

6. The DTW-based real-time diagnosis method for a CF of a phase-controlled converter according to claim 1, wherein in the step 6, the λ is 1.5.

7. The DTW-based real-time diagnosis method for a CF of a phase-controlled converter according to claim 3, wherein the q1 is 0.5, the q2 is 0.8, and the q3 is 1.3.
